(19) United States
(12) Patent Application Publication
(10) Pub. No.: US 2021/0151576 A1
(43) Pub. Date: May 20, 2021

(54) THIN FILM TRANSISTOR AND MANUFACTURING METHOD FOR THIN FILM TRANSISTOR

(71) Applicant: Japan Display Inc., Tokyo (JP)

(72) Inventors: Takeshi SAKAI, Tokyo (JP); Tatsuya TODA, Tokyo (JP); Masashi TSUBUKU, Tokyo (JP)

(21) Appl. No.: 17/162,367

(22) Filed: Jan. 29, 2021

Related U.S. Application Data
(63) Continuation of application No. PCT/JP2019/022885, filed on Jun. 10, 2019.

(30) Foreign Application Priority Data
Aug. 8, 2018 (JP) 2018-149154

(51) Int. Cl. H01L 29/45; H01L 29/24; H01L 29/786; H01L 21/02; H01L 21/443; H01L 21/4763; H01L 29/66

(52) U.S. Cl. CPC H01L 29/45; H01L 29/247; H01L 29/78636; H01L 29/78693; H01L 21/02071; H01L 27/3262; H01L 21/02592; H01L 21/443; H01L 21/47635; H01L 29/66969; H01L 21/02565

(57) ABSTRACT

A thin film transistor comprising an active layer made of an oxide semiconductor containing indium and gallium, an electrode layer including a titanium layer formed on the active layer, wherein an indium concentration is equal to or less than 1.3 times an oxygen concentration in a range of 15 nm from an interface between the active layer and the electrode layer toward the active layer.

### CROSS-REFERENCE TO RELATED APPLICATION

The present application is Bypass Continuation of International Application No. PCT/JP2019/022885, filed on Jun. 10, 2019, which claims priority from Japanese Application No. JP2018-149154 filed on Aug. 8, 2018. The contents of these applications are hereby incorporated by reference into this application.

### BACK GROUND

### 1. Field

The present invention relates to a thin film transistor and a method for manufacturing the thin film transistor.

### 2. Description of the Related Art

JP2017-46002A discloses that a semiconductor device having a bottom-gate transistor, in which an insulating layer functioning as a channel protective film is provided on an oxide semiconductor film, removes impurities after forming an insulating layer provided in contact with the oxide semiconductor film and/or a source electrode layer and a drain electrode layer, thereby preventing elements contained in etching gas from remaining as impurities on the surface of the oxide semiconductor film. In the disclosure of JP2017-46002A, the impurity concentration at the surface of the oxide semiconductor film is 5×10¹⁸ atoms/cm³ or less, preferably 1×10¹⁸ atoms/cm³ or less.

JP2011-129897A discloses that a thin film transistor using oxide semiconductors and having good electrical properties includes a gate electrode provided on a substrate, a gate insulating film provided on the gate electrode, an oxide semiconductor film provided on the gate electrode and the gate insulating film, a metal oxide film provided on the oxide semiconductor film, a metal film provided on the metal oxide film, where the oxide semiconductor film is in contact with the metal oxide film and includes an area having a higher metal concentration than other areas of the oxide semiconductor film (high metal concentration area).

### SUMMARY

In TAOS-TFT (Transparent Amorphous Oxide Semiconductor-Thin Film Transistor) using an oxide semiconductor such as IGO and IGZO containing group 13 elements, such as indium, gallium, and zinc, as an active layer, the applicant has found that a voltage (negative gate voltage) applied to the gate electrode in such a way that the gate-source voltage becomes negative may lower the current at a low drain voltage over time. This is observed as a resistance increase at a low voltage occurring due to degradation over time caused by long-term use of the TAOS-TFT or use of the TAOS-TFT under high stress. For example, when the TAOS-TFT is used for pixel voltage control of LCD (Liquid Crystal Display) or OLED (Organic Electro Luminescence Display), there may be a risk of decrease in color rendering at low brightness.

One or more embodiments of the present invention have been conceived in view of the above, and an object thereof is to reduce a current drop over time at a low drain voltage in a transistor having an oxide semiconductor as an active layer as described above.

The invention disclosed in the present application in order to solve the above problem has various aspects, and a summary of representative of those aspects is as follows.

A thin film transistor comprising an active layer made of an oxide semiconductor containing indium and gallium, an electrode layer including a titanium layer formed on the active layer, wherein an indium concentration is equal to or less than 1.3 times an oxygen concentration in a range of 15 nm from an interface between the active layer and the electrode layer toward the active layer.

The thin film transistor wherein an indium concentration is equal to or lower than an oxygen concentration in a range of 15 nm from an interface of the active layer and the electrode layer toward the active layer.

A thin film transistor comprising an active layer made of an oxide semiconductor containing indium and gallium, an electrode layer including a metal layer containing titanium formed on the active layer, wherein an amount of indium is equal to or less than an amount of oxygen in a range of 15 nm from an interface of the active layer and the electrode layer toward the active layer.

The thin film transistor wherein an amount of residual chlorine on a surface of the active layers is equal to or less than 1.0×1019 [atoms/cm3].

The thin film transistor wherein an amount of residual chlorine on a surface of the active layer is equal to or less than 1.0×1019 [atoms/cm3].

A manufacturing method for a thin film transistor, the method comprising steps of forming an active layer made of an oxide semiconductor containing indium and gallium on a substrate; forming an electrode layer including a metal layer containing titanium on the active layer; forming a resist layer on the electrode layer; patterning the metal layer by etching; removing the resist layer; and reducing an amount of residual chlorine on a surface of the active layer after removing the resist layer to be equal to or less than 1.0×1019 [atoms/cm3].

### BRIEF DESCRIPTION OF THE DRAWINGS

FIG. 1 is a diagram for illustrating a cross section of a transistor according to an embodiment of the present invention;

FIG. 2 is an enlarged cross-sectional view of the vicinity of an oxide semiconductor layer of the transistor;

FIG. 3 is a graph showing ion concentrations of elements in a composition ratio in a direction from a drain electrode toward the oxide semiconductor layer when an amount of residual chlorine is not reduced.

FIG. 4 is a graph showing ion concentrations of elements in the composition ratio in the direction from the drain electrode toward the oxide semiconductor layer when the amount of residual chlorine is reduced to 1.0×10¹⁹ [atoms/cm³] or less;

FIG. 5 is a diagram illustrating a transistor according to an embodiment of the present invention and a display device, which is an OLED, using the transistor and a manufacturing process of the display device; and

FIG. 6 is a diagram illustrating a transistor according to an embodiment of the present invention and a display device, which is an LCD, using the transistor and a manufacturing process of the display device.

### DETAILED DESCRIPTION

Embodiments of the present invention will be described below in detail with reference to the accompanying drawings. The disclosure is merely an example, and appropriate modifications while keeping the gist of the invention that can be easily conceived by those skilled in the art are naturally included in the scope of the invention. The accompanying drawings may schematically illustrate widths, thicknesses, shapes, or other characteristics of each part for clarity of illustration, compared to actual configurations. However, such a schematic illustration is merely an example and not intended to limit the present invention. In this specification and each drawing, the same elements as those already described with reference to the already-presented drawings are denoted by the same reference numerals, and detailed description thereof may be appropriately omitted.

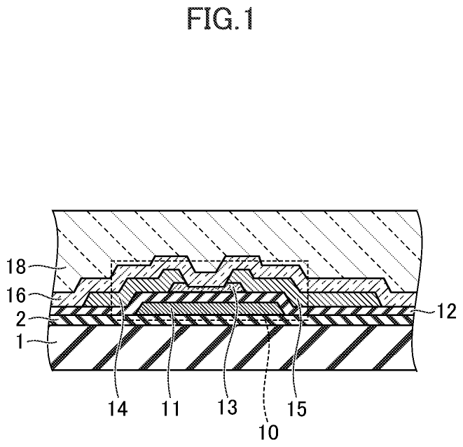

FIG. 1 is a diagram for illustrating a cross section of a transistor 10 according to an embodiment of the present invention.

The transistor 10 is a thin film transistor formed on an undercoat layer 2 on a substrate 1 using a photolithographic technique. The substrate 1 is an inorganic or an organic substrate, such as a glass substrate, a quartz substrate, and a resin substrate, and may be rigid or flexible. The undercoat layer 2 is a film that functions as a barrier layer for preventing diffusion of impurities contained in the substrate 1 to the thin film transistor.

A gate electrode layer 11 is formed on the undercoat layer 2. The gate electrode layer 11 may be formed of metal or an alloy layer, or conductive metal oxide or other conductive materials, and preferably formed of a low-resistance material. In FIG. 1, the gate electrode layer 11 is shown as if a single layer, but may be a single layer or a laminate of a plurality of materials. A gate insulating layer 12 is formed on the gate electrode layer 11, and an oxide semiconductor layer 13 is formed on an area that is on the gate insulating layer 12 and overlaps the gate electrode layer 11. The oxide semiconductor layer 13 is an active layer of the transistor 10, and a metal oxide containing at least indium and gallium in the group 13 elements. In the present embodiment, the oxide semiconductor layer 13 is a transparent semiconductor made of oxides of indium, gallium, and zinc known as IGZO.

A source electrode 14 and a drain electrode 15 are formed on the oxide semiconductor layer 13 and the gate insulating layer 12 so as to be partially in contact with the oxide semiconductor layer 13. The source electrode 14 and the drain electrode 15 are not in contact with each other and disposed apart at a predetermined distance. As such, the oxide semiconductor layer 13 has a part that is not covered by the source electrode 14 and the drain electrode 15. Further, although the source electrode and the drain electrode 15 may be a single layer or multiple layers, titanium is included at least in the layer in contact with the oxide semiconductor layer 13.

An interlayer insulating layer 16 and a flattening layer 18 are formed on the oxide semiconductor layer 13, the source electrode 14, and the drain electrode 15. The transistor 10 is thus formed on the substrate 1. Depending on the application of the transistor 10, a through hole penetrating the flattening layer 18 and the interlayer insulating layer 16 is further formed as appropriate so that the source electrode 14 and the drain electrode 15 are connected to the appropriate electrical circuit formed on the flattening layer 18. A device having the transistor 10 is thus formed. Examples of such a device include displays such as an LCD and an OLED.

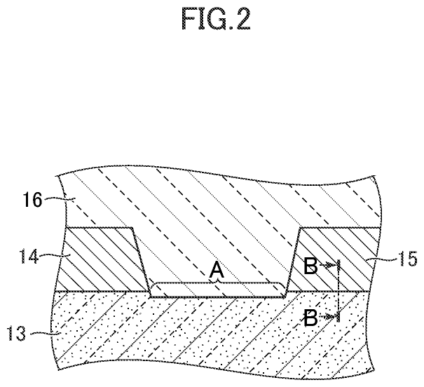

FIG. 2 is an enlarged cross-sectional view of the vicinity of the oxide semiconductor layer 13 of the transistor 10. The source electrode 14 and the drain electrode 15 are formed on the upper surface of the oxide semiconductor layer 13, and the oxide semiconductor layer 13 is exposed upward between the source electrode 14 and the drain electrode 15 so as to form an area A in directly contact with the interlayer insulating layer 16.

The present embodiment features that an amount of residual chlorine on the surface of the oxide semiconductor layer 13 is 1.0×10¹⁹ [atoms/cm³] or less in the area A. Such a feature will be described below.

In the manufacturing process of the transistor 10, a metal layer formed on the oxide semiconductor layer 13 is etched to form the source electrode 14 and the drain electrode 15. The etching method is not particularly limited. Here, the metal layer is removed by dry etching until the surface of the oxide semiconductor layer 13 in the area A is exposed. The parts to be the source electrode 14 and the drain electrode 15 are protected by a resist film so that the metal layer is not removed.

At this time, impurities such as etching gas are adhered to the surface of the area A of the oxide semiconductor layer 13. Particularly important is that chlorine derived from the etching gas is adhered to the surface. A considerable part of such impurities is washed away during the peel cleaning of the resist film protecting the source electrode 14 and the drain electrode 15, and a part of the impurities remains as residual chlorine.

The Applicant has found that such residual chlorine is not an immediate problem in the use of the transistor 10, but indirectly causes a current drop at a low drain voltage. That is, when a negative gate voltage is applied to the transistor 10, a current may drop at the low drain voltage over time.

Examples of the negative voltage may include excessive negative voltage (e.g., −30 V) applied for several hours to several days in total, or not excessive negative voltage (e.g., −5 V) applied repeatedly over a long period of time, such as for several months to several years.

Such current drop at the low drain voltage may be caused by a thin film layer of high resistance formed at the interface of the source electrode 14 or the drain electrode 15 and the oxide semiconductor layer 13, and the interface resistance is thereby increased only at a low voltage. The thin film layer of high resistance is considered to be due to titanium oxide.

As a result of the analysis, chlorine that should not originally exist at the interface between the source electrode 14 and/or the drain electrode 15 and the oxide semiconductor layer 13 was detected in the transistor 10 after aging. Although the detailed mechanism is unknown, the applicant speculates that chlorine remaining as indium chloride on the surface of the oxide semiconductor layer 13 after the resist film is removed is moved to the interface between the oxide semiconductor layer 13 and the source electrode 14 or the drain electrode 15 after the transistor 10 is formed, and a negative gate voltage is applied, which causes the titanium oxide to be gradually precipitated.

Accordingly, the applicant attempted to remove the chlorine during the resist removal cleaning so as to reduce an amount of residual chlorine on the surface of the oxide semiconductor layer 13. As a result, it has been found that, when the amount of residual chlorine is reduced to 1.0×10¹⁹ [atoms/cm³] or less, the current drop at the low drain voltage can be effectively prevented even if a negative gate voltage is continuously applied. The chlorine is removed by appropriately selecting stripping solutions and changing the cleaning conditions at the time of resist removing.

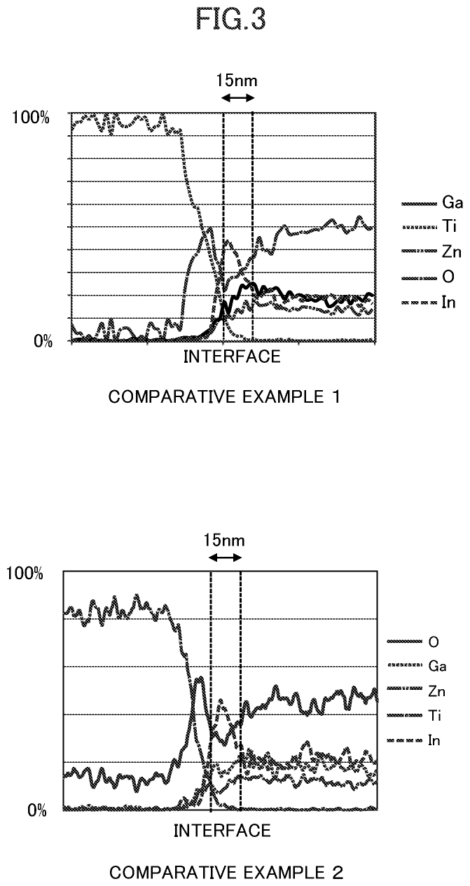

FIG. 3 is a graph showing ion concentrations of the elements in the composition ratio in the direction from the drain electrode 15 toward the oxide semiconductor layer 13 when the amount of residual chlorine is not reduced. The graph shows the change in the ion concentration regarding oxygen, titanium, zinc, gallium, and indium along the B-B line in FIG. 2 in a composition ratio, and the measured samples are different in the graph shown as Comparative example 1 and the graph shown as Comparative example 2.

In the graph, the vertical axis represents the composition ratio of the ion concentration, and the horizontal axis represents the distance, and the left direction in the graph corresponds to the drain electrode 15 side, and the right direction corresponds to the oxide semiconductor layer 13 side. Further, the position shown as “interface” in the graph is the interface between the drain electrode 15 and the oxide semiconductor layer 13.

As is clear from the graph shown in FIG. 3, the position of the interface itself is not obvious, and thus it is necessary to reasonably determine the position of the interface. In this specification, the layer in contact with the oxide semiconductor layer 13 of the drain electrode 15 contains titanium as an electrode material, and the point where the composition ratio of the titanium is 10% is defined as the interface. As another example, the point where the composition ratio of titanium exceeds any of the composition ratio of the main elements constituting the oxide semiconductor layer 13, such as gallium and indium, which are the group 13 elements, may be defined as the interface. Other reasonable definitions may be used.

The oxide semiconductor layer 13 used in the Comparative examples 1 and 2 is a so-called IGZO, and is formed so as to originally have a composition ratio of zinc, gallium, and indium of 1:1:1. However, as is clear from FIG. 3, only the indium concentration increases remarkably in the range of about 15 nm from the interface toward the oxide semiconductor layer 13 (in the right direction in the graph), and the oxygen concentration decreases accordingly.

In other words, in the Comparative examples 1 and 2, there is a point where the indium concentration remarkably exceeds the oxygen concentration in the ion concentration in a range of 15 nm from the interface toward the oxide semiconductor layer 13, which is an active layer. Specifically, there is a point where the indium concentration exceeds 1.3 times the oxygen concentration.

In the Comparative examples 1 and 2, an amount of indium exceeds an amount of oxygen in an amount of ion in the range of 15 nm from the interface toward the oxide semiconductor layer 13, which is the active layer. An amount of ion of a specific element in a specific range is an integrated value of the ion concentration in such a range and, in the graph of FIG. 3, corresponds to an area on the lower side of the ion concentration curve in the specific range. In both Comparative examples 1 and 2, the amount of indium exceeds the amount of oxygen in the range of 15 nm from the interface.

On the other hand, in the range exceeding 15 nm from the interface toward the oxide semiconductor layer 13, the element composition ratio of the oxide semiconductor layer 13 becomes as substantially intended, and thus no special consideration should be needed for this range.

For the sample of the Comparative examples 1 and 2, when −30 V as a negative voltage is applied to the gate voltage for 1 hour, the drain current at the low drain voltage is reduced (i.e., the drain resistance is increased), and the transistor 10 is confirmed to be deteriorated over time.

Although the mechanism of this occurrence is not clear as described above, it is considered that, when or after the chlorine remaining on the oxide semiconductor layer 13 moves to the interface between the drain electrode 15 and the oxide semiconductor layer 13, the indium concentration is increased and the oxygen concentration is decreased in the range of 15 nm from the interface toward the oxide semiconductor layer 13, and then titanium oxide is generated in the presence of a reverse gate voltage by the increased indium or the chlorine combined with the indium.

As such, an increase in the indium concentration is prevented in the range of 15 nm from the interface toward the oxide semiconductor layer 13 to a certain level of concentration or less, whereby it is expected to prevent a decrease in the drain current at the low drain voltage over time.

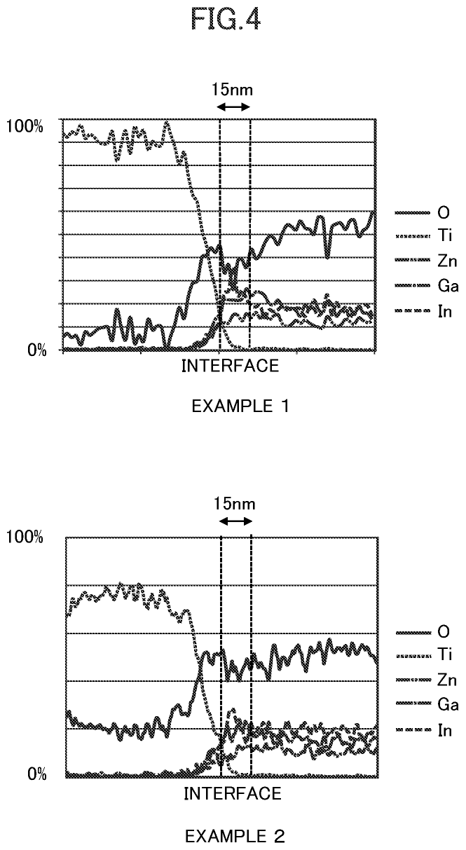

FIG. 4 is a graph showing ion concentrations of elements in the composition ratio in the direction from the drain electrode 15 toward the oxide semiconductor layer 13 when the amount of residual chlorine is reduced to 1.0×10¹⁹ [atoms/cm³] or less. Similarly to the graph shown in FIG. 3, the graph in FIG. 4 shows the change in the ion concentration regarding oxygen, titanium, zinc, gallium and indium along the B-B line in FIG. 2 in a composition ratio, and the measured samples are different in the graph shown as Example 1 and the graph shown as Example 2. The vertical axis and the horizontal axis of the graph are displayed in the same way as FIG. 3.

As shown in FIG. 4, in the samples shown in the Example 1 and the Example 2, the indium concentration is generally below the oxygen concentration in the ion concentration in the range of 15 nm from the interface toward the oxide semiconductor layer 13, which is an active layer. As seen in Example 1, although there is a part where the indium concentration partially exceeds the oxygen concentration, the indium concentration does not exceed 1.3 times the oxygen concentration and is lower than that.

In the Examples 1 and 2, the amount of indium does not exceed the amount of oxygen and is lower than the amount of oxygen in the range of 15 nm from the interface toward the oxide semiconductor layer 13, which is an active layer.

In the samples of the Examples 1 and 2, when −30 V as a negative voltage was applied to the gate voltage for 1 hour, the current drop was also not observed at a low drain voltage. That is, an increase in the indium concentration was prevented in the range of 15 nm from the interface toward the oxide semiconductor layer 13, whereby the resistance to deterioration of the transistor 10 over time was increased.

As can be seen from the above description, it is preferable that the indium concentration does not increase or is small in the range of 15 nm from the interface between the drain electrode 15 and the oxide semiconductor layer 13 toward the oxide semiconductor layer 13, which is an active layer. It is more preferable that the indium concentration is equal to or less than 1.3 times the oxygen concentration, more preferably, the indium concentration is equal to or less than the oxygen concentration.

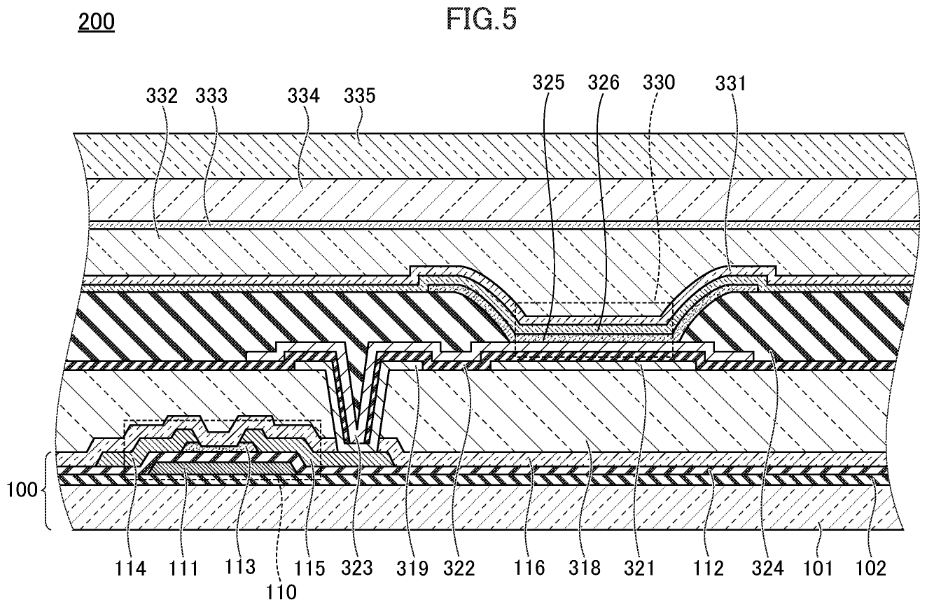

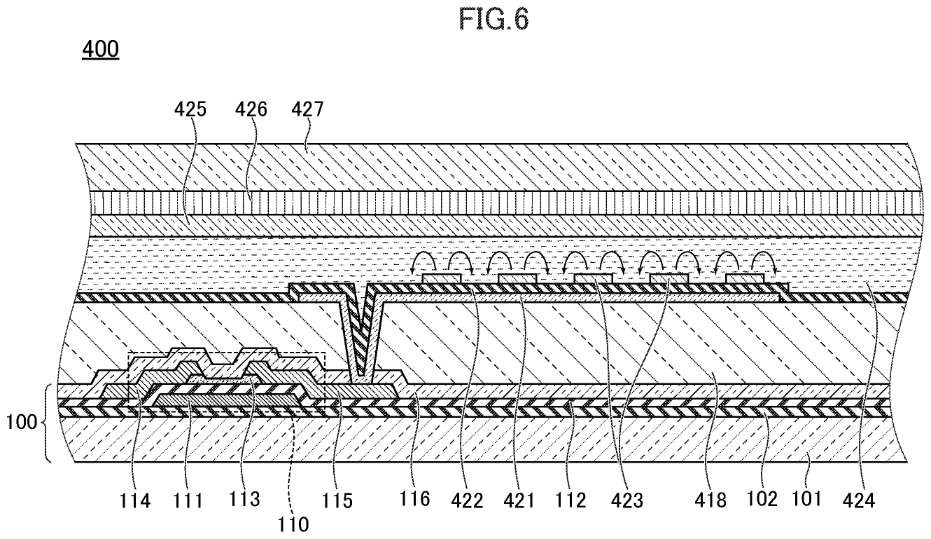

Next, referring to FIGS. 5 and 6, a transistor according to an embodiment of the present invention and a manufacturing process of a display device using the transistor will be described.

### <Manufacture of Transistor 110> (FIGS. 5 and 6)

A substrate 101 is prepared. Examples of the substrate 101 include a glass substrate, a quartz substrate, and a resin substrate. A resin substrate provides flexibility to the substrate 101.

An undercoat layer 102 is formed on the substrate 101. One of the purposes of the undercoat layer 102 is to serve as a barrier film for preventing an impurity contained in the substrate 101 or an impurity entered from the back surface of the substrate 101 from diffusing into the transistor. In this case, the undercoat layer 102 may be formed of silicon nitride, silicon nitride oxide, aluminum nitride, aluminum nitride oxide, aluminum oxide, which have excellent barrier properties, or a laminated film containing these materials.

A gate electrode layer 111 is formed on the undercoat layer 102. The gate electrode layer 111 may use a metal such as aluminum, titanium, chromium, molybdenum, tantalum, and tungsten, or an alloy containing these metals. The gate electrode of the transistor may use not only the metal materials described above but also a transparent conductive material, such as ITO and IZO. In a case where the gate electrode layer is used not only as the gate electrode of the transistor but as a conductive layer for forming surrounding wiring, it is more preferable to use the metal material described above, since low resistance is required. The gate electrode layer 111 may be formed to have a thickness of about 50 nm to 700 nm, preferably 100 nm to 500 nm. In FIG. 5, the gate electrode layer 111 is represented as a single layer, but may be a laminate of a plurality of materials.

A gate insulating layer 112 is formed on the gate electrode layer 111. The gate insulating layer 112 may be formed of silicon nitride, silicon nitride oxide, silicon oxide, or a laminated film containing these materials. The gate insulating layer 112 may be formed to have a thickness of about 50 nm to 700 nm, preferably about 100 nm to 500 nm.

An oxide semiconductor layer 113 is formed on the gate insulating layer 112 and in an area to overlap with the gate electrode layer 111 formed previously. The oxide semiconductor layer 113 is typically a metal oxide containing a group 13 element such as indium and gallium, and specifically, IGO and IGZO. The oxide semiconductor layer 113 may contain other elements, such as tin belonging to a group 14 element, and titanium and zirconium belonging to a group 4 element. The oxide semiconductor layer 113 may be formed to have a thickness of about 5 nm to 100 nm, preferably 5 nm to 60 nm.

The crystallinity of the oxide semiconductor layer 113 is not particularly limited, and may be any of a single crystal, a polycrystal, and a microcrystal. Alternatively, the oxide semiconductor layer 113 may be amorphous. The characteristics of the oxide semiconductor layer 113 may preferably include few crystal defects such as oxygen deficiency, and a low hydrogen content concentration. This is because hydrogen contained in the oxide semiconductor layer 113 functions as a donor and induces a current leakage of the transistor.

A wiring layer is formed so as to be in contact with the oxide semiconductor layer 113. The source electrode 114 and the drain electrode 115 shown in FIGS. 5 and 6 are formed as a part of the wiring layer. Similarly to the gate electrode layer 111, the wiring layer may use a metal such as aluminum, titanium, chromium, molybdenum, tantalum, and tungsten, or an alloy containing any of these metals. The wiring layer 114 is formed in contact with the oxide semiconductor layer 113. As such, the surface of the wiring layer 114 in contact with the oxide semiconductor layer 113 may preferably be formed of a material having ohmic resistive properties at the connection part of the wiring layer 114 and the oxide semiconductor layer 113, and includes at least titanium in the present embodiment. The wiring layer 114 may be formed to have a thickness of about 50 nm to 1 μm, preferably 300 nm to 700 nm.

The wiring layer is patterned by etching. Any suitable etching method may be selected depending on conditions. In the present embodiment, a photosensitive resist film is formed on the wiring layer, and then a mask pattern is formed by photolithography. Subsequently, an excess metal film of the wiring layer is removed by dry etching using an etching gas. At this time, a part of the surface of the oxide semiconductor layer 113 is slightly etched, and chlorine contained in the etching gas is attached to the surface of the oxide semiconductor layer 113. Subsequently, the resist film on the wiring layer is removed using a stripping solution. At this time, the residual chlorine adhered on the oxide semiconductor layer 13 is reduced to 1.0×10¹⁹ [atoms/cm³] or less.

With the above patterning, the wiring layer is formed to serve as the source electrode 114 and the drain electrode 115. In the above steps, the transistor 110 and the surrounding wiring layer (not shown) are formed.

### <Manufacture of Display Device 200> (FIG. 5)

After the transistor 110 is formed, an interlayer insulating layer 116 overlying the transistor 110 and a flattening layer 318 are formed. The interlayer insulating layer 116 is partially in contact with the oxide semiconductor layer 113, and thus, similarly to the gate insulating layer 112 and the undercoat layer 102, may be formed of silicon nitride, silicon nitride oxide, and silicon oxide, or a laminated film containing these materials. The interlayer insulating layer 116 may be formed to have a thickness of about 50 nm to 700 nm, preferably 100 nm to 500 nm. One of the purposes to provide the flattening layer 318 is to reduce the unevenness of the transistor 110, for example. The flattening layer 318 may use a thermosetting or a photocuring organic resin. The flattening layer 318 may be formed to have a thickness about 300 nm to 2 μm, preferably 500 nm to 1 μm.

A contact hole is formed in the interlayer insulating layer 116 and the flattening layer 318 so as to reach the source electrode 114 or the drain electrode 115. Thereafter, a pixel electrode 323 to be electrically connected to the drain electrode 115 through the contact hole is formed. As shown in FIG. 5, after the contact hole is formed, a conductive layer 319 may be formed so as to cover the contact hole, and a conductive layer 321 may be formed at the same time. One of the purposes to provide the conductive layer 319 is to improve the connection between the source electrode 114 or the drain electrode 115 and the pixel electrode 323. The conductive layer 321 is provided so as to overlap with the pixel electrode 323 via a capacitance insulating layer 322 and to form a capacitance at the overlapped portion.

Here, the pixel electrode 323 functions as an anode of the organic EL element 330. When the display device 200 is configured as a top emission type, the pixel electrode 323 is formed as a reflecting electrode. At this time, the pixel electrode 323 is required to have a good surface reflectivity and the work function for functioning as an anode of the organic EL element 330. In order to satisfy these requirements, the pixel electrode 323 may be formed as a laminated film of highly reflective aluminum and silver having the outermost surface made of an indium-based oxide conductive layer, such as ITO and IZO. The pixel electrode may be formed such that a thickness of the reflective layer made of materials such as aluminum and silver is about 50 nm to 300 nm, preferably 100 nm to 200 nm, and the surface layer made of ITO and IZO formed thereon is about 5 nm to 100 nm, preferably 10 nm to 50 nm.

Subsequently, an insulating layer 324 is formed so as to cover the end of the pixel electrode 323 and provide an opening exposing the upper surface of the pixel electrode 323. An area corresponding to the upper surface of the pixel electrode 323 exposed from the insulating layer 324 is to be a light emitting area of the organic EL device later. The insulating layer 324 functions as a member for separating adjacent pixel electrodes 323, and is thus generally referred to as a “partition wall,” “bank,” and “rib.” The insulating layer 324 may be preferably formed to have a flat upper surface and a smooth tapered side wall of the opening portion, and may use a thermosetting or a photocuring organic resin similarly to the flattening layer 318. The insulating layer 324 may be formed to have a thickness of about 300 nm to 2 μm, preferably 500 nm to 1 μm.

An organic layer 325 is formed so as to cover the exposed pixel electrode 323. The organic layer 325 includes at least a light-emitting layer, and functions as a light-emitting part of the organic EL element 330. The organic layer 325 may include charge transport layers, such as a hole injection layer, a hole transport layer, an electron injection layer, and an electron transport layer, in addition to the light-emitting layer, and may further include charge block layers, such as a hole block layer and an electron block layer. The thickness of the organic layer 325 varies depending on the included layers and its optical properties, and may be about 5 nm to 500 nm, preferably 10 nm to 150 nm. In FIG. 5, the organic layer 325 is provided on one pixel electrode 323, but may be continuously formed on a plurality of pixel electrodes 323 and the insulating layer 324.

After the organic layer 325 is formed, a counter electrode 326 is formed. Here, the counter electrode 326 functions as a cathode of the organic EL device 330. When the display device 200 is configured as a top emission type, the counter electrode 326 is formed as a transparent electrode. At this time, the counter electrode 326 is required to have a high transmittance that does not interfere with light emission from the organic layer 325 and a work function for functioning as a cathode of the organic EL element 330. In order to satisfy these requirements, the counter electrode 326 may be formed as an indium-based oxide transparent conductive layer, such as ITO and IZO, or a thin film made of magnesium, silver, or an alloy or a compound thereof and having thickness to ensure enough transmittance. When using an indium-based oxide transparent conductive layer, the counter electrode 326 may be formed to have a thickness of about 50 nm to 500 nm, preferably 100 nm to 300 nm, and when using magnesium, silver, or an alloy or a compound thereof, a thickness of about 5 nm to 50 nm, preferably 10 nm to 30 nm. The counter electrode 326 is a common electrode for a plurality of organic EL elements 330, and formed continuously on a plurality of pixel electrodes 323 and the insulating layer 324.

The functions of the organic EL element 330 are easily deteriorated due to penetration of moisture, and thus, a sealing layer is formed. FIG. 5 shows an example of a sealing layer including an inorganic insulating layer 331, an organic insulating layer 332, and an inorganic insulating layer 333. The inorganic insulating layers 331 and 333 may be formed of silicon nitride, silicon nitride oxide, aluminum nitride, aluminum nitride oxide, aluminum oxide, which have excellent barrier properties, or a laminated film containing these materials. The organic insulating layer 332 may use an organic resin of a thermosetting type or a photocuring type. The sealing layer has a laminate structure of the inorganic insulating layers 331 and 333 and the organic insulating layer 332, and thus it is possible to prevent seal failures due to particles mixed in the process. The thickness of the sealing layer may be about 300 nm to 2 μm, preferably 500 nm to 1 μm in the inorganic insulating layers 331 and 333, and about 1 μm to 20 μm, preferably 2 μm to 10 μm in the organic insulating layer 332.

With the steps described above, the display device 200 as an OLED is manufactured. As shown in FIG. 5, a counter substrate 335 may be provided on the inorganic insulating layer 333 with an adhesive 334 interposed therebetween. The counter substrate 335 may have a function of a cover glass and a touch sensor, for example.

### <Manufacture of Display Device 400> (FIG. 6)

After the transistor 110 is formed, an interlayer insulating layer 116 overlying the transistor 110 and a flattening layer 418 are formed. The interlayer insulating layer 116 is partially in contact with the oxide semiconductor layer 113, and thus, similarly to the undercoat layer 102 and the gate insulating layer 112, may be formed of silicon nitride, silicon nitride oxide, and silicon oxide, or a laminated film containing these materials. The interlayer insulating layer 116 may be formed to have a thickness of about 50 nm to 700 nm, preferably 100 nm to 500 nm. One of the purposes to provide the flattening layer 418 is to reduce the unevenness of the transistor 110, for example. The flattening layer 418 may use a thermosetting or a photocuring organic resin. The flattening layer 418 may be formed to have a thickness about 300 nm to 2 μm, preferably 500 nm to 1 μm.

A contact hole is formed in the interlayer insulating layer 116 and the flattening layer 418 so as to reach the drain electrode 115. Thereafter, a pixel electrode 421 to be electrically connected to the drain electrode 115 through the contact hole is formed. The pixel electrode 421 may use an indium-based oxide transparent conductive layer, such as ITO and IZO. The pixel electrode 421 may be formed to have a thickness of about 50 nm to 500 nm, preferably 100 nm to 300 nm.

Common electrodes 423 are formed on the pixel electrode 421 with the insulating layer 422 therebetween. Similarly to the pixel electrode 421, the common electrodes 423 may use an indium-based oxide transparent conductive layer, such as ITO and IZO. In FIG. 6, the common electrodes 423 are illustrated discretely, although they are connected to each other when viewed in plan and formed in a comb-like or a plate shape having slits. The shapes of the pixel electrode 421 and the common electrode 423 are not limited to this example, and the pixel electrode in a comb-like or a plate shape having slits may be formed on the common electrodes formed in a plate shape with the insulating layer 422 therebetween.

The color filter 426 and the overcoat layer 425 are formed on the counter substrate 427 and disposed so as to face the substrate 101, and a liquid crystal layer 424 is provided in the gap between the counter substrate 427 and the substrate 101. In the liquid crystal layer 424, the alignment direction of the liquid crystal is controlled by the lateral electric field applied by the pixel electrode 421 and the common electrode 423 described above as indicated by the arrow, and the transmittance of the light beam is controlled.

With the steps described above, the display device 400, which is an LCD, is manufactured.

In the display devices 200 and 400 described above, the transistor 110 in which the pixel electrodes 323 and 421 are connected to the drain electrode 115 does not generate a decrease in the drain current at the low drain voltage even when a negative gate voltage is repeatedly applied. As such, it is possible to maintain good gradation representation for a long period of time.

The present invention is not limited to the above embodiment, and various modifications can be made. For example, a replacement can be made with a configuration that is substantially the same as the configuration shown in the above-described embodiment, a configuration that exhibits the same operational effect, or a configuration that can achieve the same object.

Within the scope of the idea of the present invention, those skilled in the art can come up with various changes and modifications and it will be understood that these changes and modifications also fall into the scope of the present invention. For example, in each of the above-described embodiments, addition, deletion or redesign of a component, or addition, omission or condition change of a process, which are appropriately made by a person skilled in the art, are also included within the scope of the present invention as long as they remain the gist of the present invention.

What is claimed is:

1. A thin film transistor comprising:
an active layer made of an oxide semiconductor containing indium and gallium, and
an electrode layer including a titanium layer formed on the active layer, wherein
an indium concentration is equal to or less than 1.3 times an oxygen concentration in a range of 15 nm from an interface between the active layer and the electrode layer toward the active layer.

2. The thin film transistor according to claim 1, wherein
an indium concentration is equal to or lower than an oxygen concentration in a range of 15 nm from an interface of the active layer and the electrode layer toward the active layer.

3. A thin film transistor comprising:
an active layer made of an oxide semiconductor containing indium and gallium, and
an electrode layer including a metal layer containing titanium formed on the active layer, wherein
an amount of indium is equal to or less than an amount of oxygen in a range of 15 nm from an interface of the active layer and the electrode layer toward the active layer.

4. The thin film transistor according to claim 1, wherein
an amount of residual chlorine on a surface of the active layers is equal to or less than 1.0×10¹⁹ [atoms/cm³].

5. The thin film transistor according to claim 3, wherein
an amount of residual chlorine on a surface of the active layer is equal to or less than 1.0×10¹⁹ [atoms/cm³].

6. A manufacturing method for a thin film transistor, the method comprising steps of:
forming an active layer made of an oxide semiconductor containing indium and gallium on a substrate;
forming an electrode layer including a metal layer containing titanium on the active layer;
forming a resist layer on the electrode layer;
patterning the metal layer by etching;
removing the resist layer; and
reducing an amount of residual chlorine on a surface of the active layer after removing the resist layer to be equal to or less than 1.0×10¹⁹ [atoms/cm³].
